(19) United States
(12) Patent Application Publication
(10) Pub. No.: US 2026/0215057 A1
(43) Pub. Date: Jul. 23, 2026

(54) DISPLAY DEVICE, METHOD FOR MANUFACTURING THE SAME, AND ELECTRONIC APPARATUS INCLUDING THE SAME

(71) Applicant: Samsung Display Co., Ltd., Yongin-Si (KR)

(72) Inventors: BYOUNG KWON CHOO, Yongin-si (KR); WOOJIN CHO, Yongin-si (KR); JOON WOO BAE, Yongin-si (KR); Sukyeong SHIN, Yongin-si (KR)

(21) Appl. No.: 19/314,411

(22) Filed: Aug. 29, 2025

(30) Foreign Application Priority Data
Jan. 23, 2025 (KR) 10-2025-0010000

(51) Int. Cl. H10H 29/49; H10H 29/01

(52) U.S. Cl. CPC H10H 29/49; H10H 29/012

(57) ABSTRACT

Provided is a display device. The display device includes at least one insulation layer disposed on a first conductive pattern and a semiconductor pattern, a second conductive pattern disposed on the at least one insulation layer and electrically connected to the first conductive pattern or the semiconductor pattern through a contact hole which penetrates the at least one insulation layer, and a light-emitting element disposed on the second conductive pattern. The second conductive pattern includes a first conductive layer which is in contact with a corresponding pattern of a conductive pattern or the semiconductor pattern and a second conductive layer which is disposed on the first conductive layer and in contact with a first side surface of the first conductive layer.

### CROSS-REFERENCE TO RELATED APPLICATIONS

This U.S. non-provisional patent application claims priority under 35 U.S.C. § 119 to Korean Patent Application No. 10-2025-0010000, filed on January 23, 2025, the entire contents of which are hereby incorporated by reference.

### BACKGROUND

The present disclosure herein relates to a display device, a method for manufacturing the same, and an electronic apparatus including the same, and more particularly, to an ultra-high resolution display device, an electronic apparatus including the same, and a method for manufacturing a display device including an electrolytic plating method.

Various types of electronic apparatuses are being developed. The electronic apparatuses may include a display device and the display device may provide information to a user.

Among the electronic apparatuses, wearable electronic apparatuses which are wearable on a body are being developed. As an example of the wearable electronic apparatuses, there is a device which is capable of being mounted on a user’s head, and such a device may be referred to as, for example, a head-mounted device (HMD). The device such as the HMD requires high resolution. As resolution increases, a design is required to increase luminous efficiency.

### SUMMARY

The present disclosure provides an ultra-high resolution display device.

The present disclosure also provides an electronic apparatus including the same.

The present disclosure also provides a method for manufacturing a display device including an efficient electrolytic plating method.

An embodiment of the inventive concept provides a display device including a base layer, a first conductive pattern disposed on the base layer, a semiconductor pattern disposed on the base layer, at least one insulation layer disposed on the first conductive pattern and the semiconductor pattern, a second conductive pattern disposed on the at least one insulation layer, and electrically connected to the first conductive pattern or the semiconductor pattern through a contact hole which penetrates the at least one insulation layer, and a light-emitting element disposed on the second conductive pattern. The second conductive pattern may include a first conductive layer which is in contact with an upper surface of the at least one insulation layer, an inner surface of the contact hole, and a corresponding pattern of the first conductive pattern or the semiconductor pattern and a second conductive layer which is disposed on the first conductive layer, and in contact with a first side surface of the first conductive layer on the upper surface of the at least one insulation layer.

In an embodiment, the first conductive layer may include a titanium layer and a copper layer disposed on the titanium layer. A side surface of the titanium layer and a side surface of the copper layer may be aligned.

In an embodiment, a thickness of the titanium layer may be about 100 Å to about 200 Å and a thickness of the copper layer may be about 300 Å to about 3000 Å.

In an embodiment, a thickness of the second conductive layer may be greater than a thickness of the first conductive layer.

In an embodiment, the second conductive layer may completely fill the contact hole on the first conductive layer.

In an embodiment, a depth of the contact hole may be about 1.6 times or more greater than a diameter of the contact hole.

In an embodiment, one side surface of the second conductive layer is aligned with a second side surface of the first conductive layer which is different from the first side surface of the first conductive layer on the upper surface of the at least one insulation layer.

In an embodiment, the display device may further include a third conductive layer disposed on the second conductive layer, wherein the second conductive layer may fill a portion of the contact hole on the first conductive layer and the third conductive layer may fill a remaining portion of the contact hole on the second conductive layer.

In an embodiment, the at least one insulation layer may include a first inorganic layer, and a second inorganic layer which is disposed on the first inorganic layer and has an upper surface in contact with the second conductive pattern. An upper surface of the second inorganic layer may have unevenness lower than that of an upper surface of the first inorganic layer.

In an embodiment, the at least one insulation layer may include an organic layer which has an upper surface in contact with the second conductive pattern.

In an embodiment of the inventive concept, an electronic apparatus may include the display device described above.

In an embodiment, the electronic apparatus may be a virtual reality (VR) device.

In an embodiment of the inventive concept, a method for manufacturing a display device includes forming a first conductive pattern and a semiconductor pattern in each of first and second cell regions of a work substrate, forming, on the work substrate, at least one insulation layer which has a contact hole exposing a corresponding pattern among the first conductive pattern and the semiconductor pattern, forming, on the insulation layer, a seed conductive layer overlapping each of the first and second cell regions, and connected to the corresponding pattern through the contact hole, forming a seed conductive pattern by patterning the seed conductive layer, forming, through an electrolytic plating method, a plating pattern which is in contact with an upper surface and a side surface of the seed conductive pattern, and forming at least one conductive pattern by patterning the seed conductive pattern and the plating pattern.

In an embodiment, in the forming of the seed conductive pattern, a voltage supply line which has an integrated shape with the seed conductive pattern may further be formed in a peripheral region of the first cell region and a peripheral region of the second cell region.

In an embodiment, the voltage supply line may have a mesh shape in a plan view.

In an embodiment, a plurality of openings may be defined in the seed conductive pattern.

In an embodiment, a thickness of the plating pattern may be greater than a thickness of the seed conductive pattern, and the plating pattern may completely fill the contact hole on the seed conductive pattern.

In an embodiment, the method for manufacturing a display device may further include forming an additional conductive pattern on the at least one conductive pattern.

In an embodiment, the plating pattern may fill a portion of the contact hole on the seed conductive pattern, and the additional conductive pattern may fill a remaining portion of the contact hole on the plating pattern.

In an embodiment, the method for manufacturing a display device may further include planarizing an upper surface of the at least one insulation layer after the forming of the at least one insulation layer and before the forming of the seed conductive layer.

In an embodiment, the seed conductive pattern may include a titanium layer and a copper layer disposed on the titanium layer. A thickness of the titanium layer may be about 100 Å to about 200 Å, and a thickness of the copper layer may be about 300 Å to about 3000 Å.

### BRIEF DESCRIPTION OF THE FIGURES

The accompanying drawings are included to provide a further understanding of the inventive concept and are incorporated in and constitute a part of this specification. The drawings illustrate embodiments of the inventive concept and, together with the description, serve to explain principles of the inventive concept. In the drawings:

FIG. 1 is a block diagram of an electronic apparatus according to an embodiment of the inventive concept;

FIG. 2 shows schematic diagrams of electronic apparatuses according to embodiments of the inventive concept;

FIG. 3 is an exploded perspective view of a virtual reality (VR) device according to an embodiment of the inventive concept;

FIG. 4A is a perspective view of a display panel according to an embodiment of the inventive concept;

FIG. 4B is an enlarged plan view of a display region of a display panel according to an embodiment of the inventive concept;

FIG. 4C is a cross-sectional view of a display panel according to an embodiment of the inventive concept;

FIG. 4D is an enlarged cross-sectional view of a partial region in FIG. 4C;

FIG. 4E is a photograph showing a conductive layer formed through a sputtering method;

FIG. 5 is a cross-sectional view of a display panel according to an embodiment of the inventive concept;

FIGS. 6A, 6B, 6C, 6D, 6E, 7A, 7B, 8A, 8B, 8C, 8D, 8E and 8F illustrate a method for manufacturing a display panel according to an embodiment of the inventive concept; and

FIG. 9 is a plan view illustrating one step of a method for manufacturing a display panel according to an embodiment of the inventive concept.

### DETAILED DESCRIPTION

In this specification, it will be understood that when an element (or a region, a layer, a portion, or the like) is referred to as being "on", "connected to" or "coupled to" another element, it may be directly disposed on, connected to, or coupled to the other element, or other elements may be disposed therebetween.

Like reference numerals or symbols refer to like elements throughout. Also, in the drawings, the thickness, ratio, and size of the elements are exaggerated for effectively describing the technical contents. As used herein, the term "and/or" includes any and all combinations of one or more of the associated listed elements.

It will be understood that, although the terms “first”, “second”, etc. may be used herein to describe various elements, the elements are not to be limited by these terms. These terms are only used to distinguish one element, component, region, layer or section from another element, component, region, layer or section. For instance, a first element, component, region, layer or section discussed below could be termed a second element, component, region, layer or section without departing from the scope of the inventive concept. Similarly, a second element, component, region, layer or section could be termed a first element, component, region, layer or section. In this specification, the singular expressions "a", "an" and "the" are intended to include the plural forms as well, unless the context clearly indicates otherwise.

In addition, the terms "below", “under”, "on the lower side", "above", “over”, "on the upper side", or the like may be used to describe the relationships between the elements illustrated in the drawings. These terms have relative concepts and are described on the basis of the directions indicated in the drawings.

It will be further understood that the terms "comprises, includes, has" and/or "comprising, including, having", when used in this specification, specify the presence of stated features, numbers, steps, operations, elements, components, or combinations thereof, but do not preclude the possibility of the presence or addition of one or more other features, numbers, steps, operations, elements, components, and/or combinations thereof.

Unless otherwise defined, all terms (including technical and scientific terms) used herein have the same meaning as commonly understood by one of ordinary skills in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the inventive concept are described with reference to the drawings.

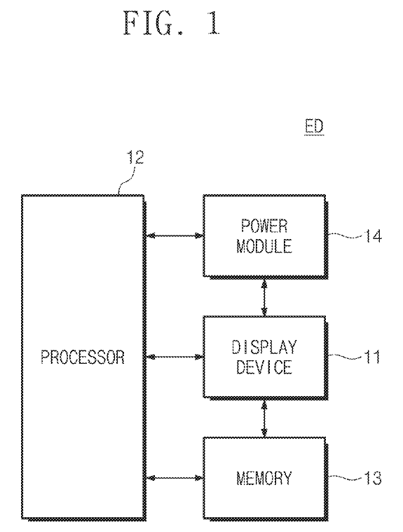

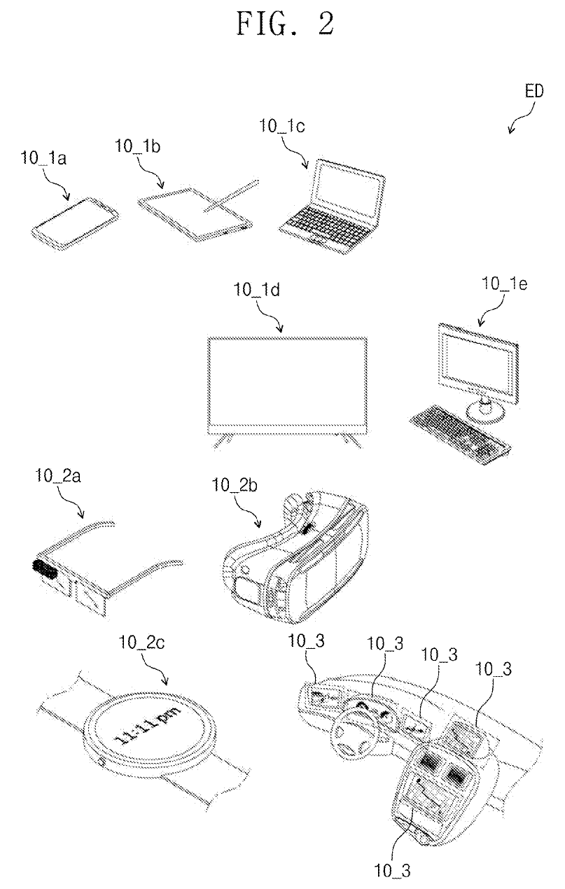

FIG. 1 is a block diagram of an electronic apparatus ED according to an embodiment of the inventive concept. FIG. 2 shows schematic diagrams of electronic apparatuses ED according to embodiments of the inventive concept.

Referring to FIG. 1, the electronic apparatus ED according to an embodiment may include a display device 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

In the memory 13, data information necessary for an operation of the processor 12 or the display device 11 may be stored. When the processor 12 executes an application stored in the memory 13, an image data signal and/or an input control signal may be transmitted to the display device 11, and the display device 11 may process the received signal and output image information through a display screen.

The power module 14 may include a power supply module such as a power adapter or battery unit, and a power conversion module which converts the power provided by the power supply module and generates power necessary for an operation of the electronic apparatus ED.

The aforementioned processor 12, power module 14, and memory 13 may be parts of the display device 11, or be a component separated from the display device 11. The processor 12, power module 14, and memory 13 may be located inside a housing, which constitutes an exterior of the electronic apparatus ED, as a component distinguished from the display device 11.

Referring to FIG. 2, an electronic apparatus ED according to an embodiment of the inventive concept may include not only a typical electronic apparatus, for information-providing purposes, such as a smart phone 10_1a, a tablet PC 10_1b, a laptop computer 10_1c, a TV 10_1d, and a monitor 10_1e for a desk , but also a wearable electronic apparatus such as smart glasses 10_2a, a head-mounted display device 10_2b, and a smart watch 10_2c, and an electronic apparatus 10_3 for vehicles such as a room mirror display and a center information display (CID), which is disposed on a car’s instrument cluster, center fascia, and dashboard.

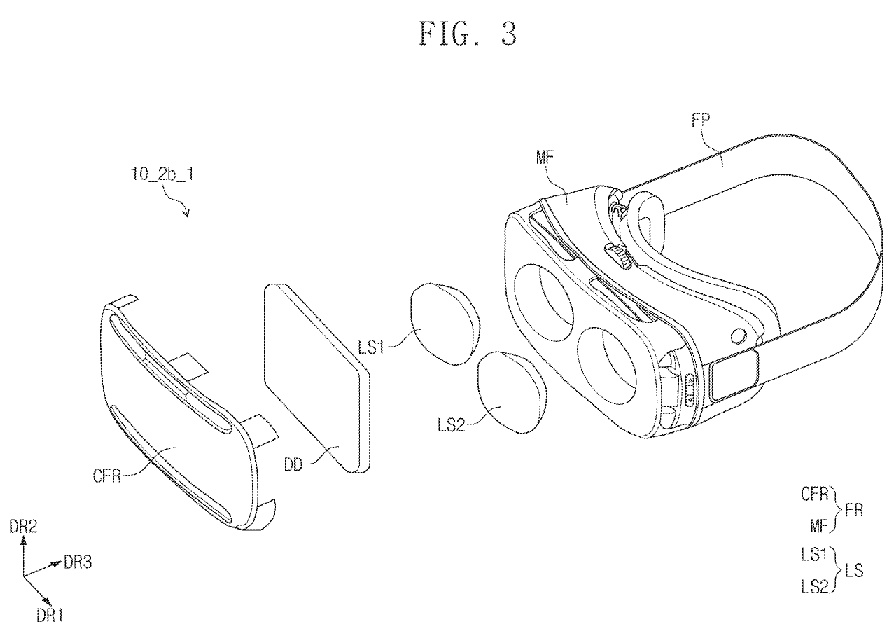

FIG. 3 is an exploded perspective view of a virtual reality device 10_2b_1 according to an embodiment of the inventive concept.

The virtual reality device 10_2b_1 in FIG. 3 may be one example of the head-mounted display device 10_2b illustrated in FIG. 2. The virtual reality device 10_2b_1 in FIG. 3 may be a see-closed type for providing virtual reality (VR) to a user with a screen that is independent from external objects.

Referring to FIG. 3, the virtual reality device 10_2b_1 may include a display device DD and a lens LS opposing the display device DD. In addition, the virtual reality device 10_2b_1 may include a frame FR (or housing) for accommodating the display device DD and the lens LS. The frame FR may include a main frame MF and a cover frame CFR. A fixing part FP may be coupled to the main frame MF and worn on a user’s head.

The cover frame CFR may be coupled to the main frame MF, and the lens LS and the display device DD may be disposed in a space therebetween. The main frame MF may provide a space where the lens LS and the display device DD are accommodated.

In a state in which a user is wearing the virtual reality device 10_2b_1, the lens LS may be located between the display device DD and the user. The lens LS may provide an image to the user by making the image generated from the display device DD pass therethrough. For example, the lens LS may include various types of lenses such as a multi-channel lens, a convex lens, a concave lens, a spherical lens, an aspherical lens, a single lens, a compound lens, a standard lens, a narrow angle lens, a wide angle lens, a fixed focus lens, and a varifocal lens. The lens LS may include a first lens LS1 and a second lens LS2. The first lens LS1 and the second lens LS2 may be disposed to respectively correspond to locations of the left eye and the right eye of the user. The display device DD may be coupled to the main frame MF in a fixed configuration, or may be coupled thereto in a detachable configuration.

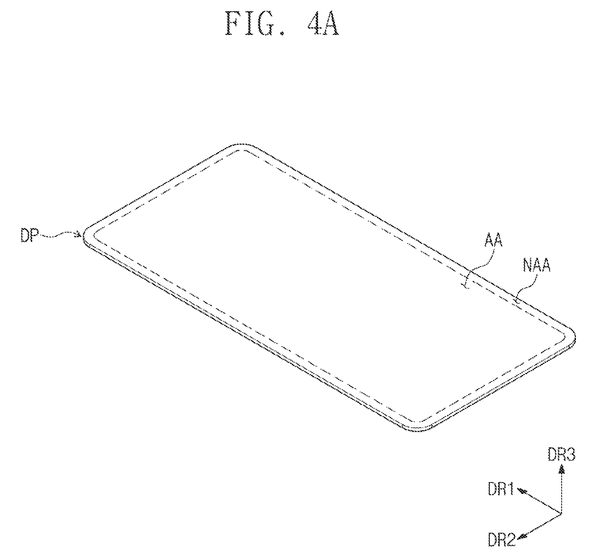

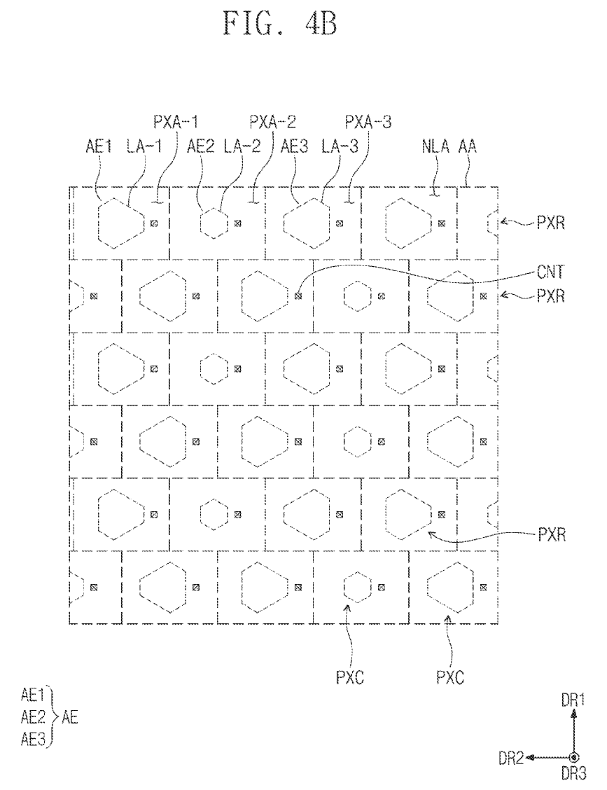

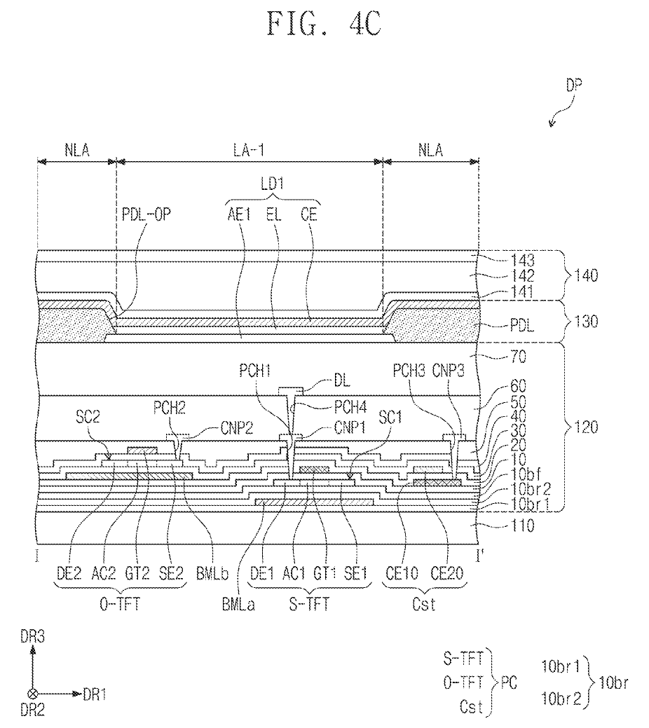

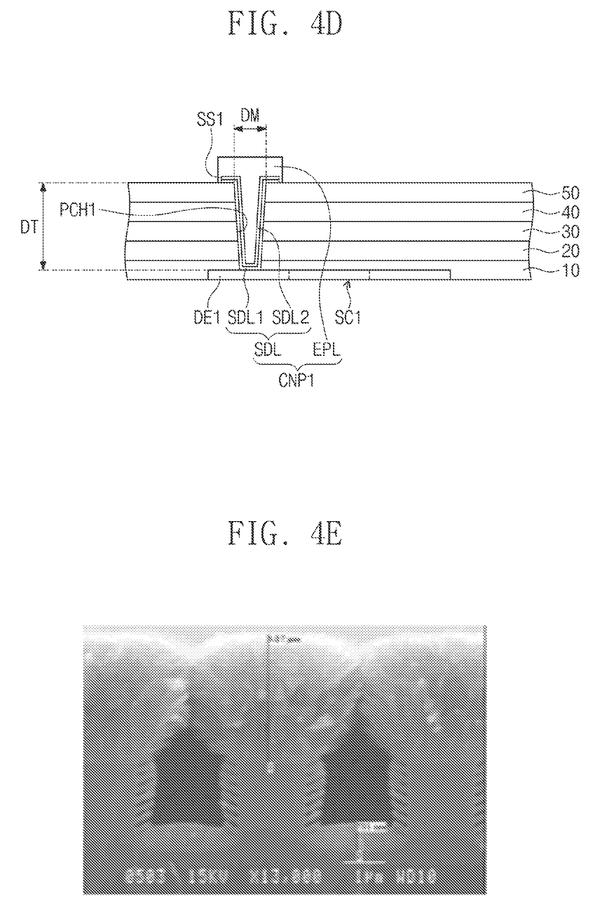

FIG. 4A is a perspective view of a display panel DP according to an embodiment of the inventive concept. FIG. 4B is an enlarged plan view of a display region AA of a display panel DP according to an embodiment of the inventive concept. FIG. 4C is a cross-sectional view of a display panel DP according to an embodiment of the inventive concept. FIG. 4D is an enlarged cross-sectional view of a partial region in FIG. 4C. FIG. 4E is a photograph showing a conductive layer formed through a sputtering method.

The display device DD described with reference to FIG. 3 may include a display panel DP to be described below. Referring to FIG. 4A, the display panel DP may include a display region AA and a peripheral region NAA. The peripheral region NAA may surround the display region AA. Pixels may be disposed in the display region AA and the pixels may not be disposed in the peripheral region NAA. The pixels may each include a light-emitting element and a pixel driving circuit for controlling the light-emitting element.

FIG. 4B illustrates an enlarged view of the display region AA. The display region AA may include a region where light is generated (or emitted) from a light-emitting element and a region where light is not generated. From this perspective, the display region AA may include a first light-emitting region LA-1, a second light-emitting region LA-2, and a third light-emitting region LA-3. The light-emitting element is disposed in each of the first light-emitting region LA-1, the second light-emitting region LA-2, and the third light-emitting region LA-3. FIG. 4B illustrates first electrodes AE of the light-emitting elements disposed in the first light-emitting region LA-1, the second light-emitting region LA-2, and the third light-emitting region LA-3. The first electrodes AE may each be connected to a conductive pattern or a semiconductor pattern disposed thereunder through a contact hole CNT.

The first light-emitting region LA-1, the second light-emitting region LA-2, and the third light-emitting region LA-3 may each be provided in plurality. The first light-emitting region LA-1, the second light-emitting region LA-2, and the third light-emitting region LA-3 may be arranged in accordance with a specific rule. The display region AA may further include a non-light emitting region NLA, which defines a boundary region of the first light-emitting region LA-1, the second light-emitting region LA-2, and the third light-emitting region LA-3, around the first light-emitting region LA-1, the second light-emitting region LA-2, and the third light-emitting region LA-3. The non-light emitting region NLA is a region where source light is not generated.

The first light-emitting region LA-1, the second light-emitting region LA-2, and the third light-emitting region LA-3 may provide light with different wavelength bands (or light with different peak wavelengths) to the outside. The first light-emitting region LA-1 may emit first color light as primary light, and the second light-emitting region LA-2 may emit second color light, which is different from the first color light, as primary light. The third light-emitting region LA-3 may emit third color light (primary light) with a different wavelength band from the first color light and the second color light.

Among the first to third light-emitting regions LA-1, LA-2, and LA-3, the third light-emitting region LA-3 may have the greatest area, and the second light-emitting region LA-2 may have the smallest area. However, this is an example, and an area comparison between the first to third light-emitting regions LA-1, LA-2, and LA-3 is not limited thereto. In this embodiment, the first color light may be blue color light, the second color light may be green color light, and the third color light may be red color light, but an embodiment of the inventive concept is not limited thereto. The first and third light-emitting regions LA-1 and LA-3 may have the same area.

In FIG. 4B, the first light-emitting region LA-1, the second light-emitting region LA-2, and the third light-emitting region LA-3 are arranged along one direction. The one direction may be a horizontal direction in FIG. 4B which may be a first direction DR1 or a second direction DR2 in FIG. 2A.

The first light-emitting region LA-1, the second light-emitting region LA-2, and the third light-emitting region LA-3 disposed within the most adjacent pixel rows PXR are not aligned within a direction crossing the one direction, and are disposed staggering each other. For example, the first light-emitting region LA-1 of a pixel row PXR, which is adjacent to any one pixel row PXR where the second light-emitting region LA-2 and the third light-emitting region LA-3 are disposed, is disposed between the second light-emitting region LA-2 and the third light-emitting region LA-3 of the any one pixel row PXR.

The light-emitting regions LA-1, LA-2, and LA-3 of odd-numbered pixel rows PXR may be arranged along a direction crossing the one direction, and the light-emitting regions LA-1, LA-2, and LA-3 of even-numbered pixel rows PXR may be arranged along a direction crossing the one direction.

In the display region AA, the pixel driving circuits of the pixels may be arranged according to a predetermined rule. A region where the pixel driving circuit of one pixel is disposed may be defined as a pixel region. The display region AA may include a first pixel region PXA-1, a second pixel region PXA-2, and the third pixel region PXA-3 respectively corresponding to the first light-emitting region LA-1, the second light-emitting region LA-2, and the third light-emitting region LA-3.

In FIG. 4B, it is illustrated that the first pixel region PXA-1, the second pixel region PXA-2, and the third pixel regions PXA-3 have a quadrangular shape, but an embodiment of the inventive concept is not limited thereto. A pixel circuit for controlling the light-emitting element disposed in the first light-emitting region LA-1 is disposed in the first pixel region PXA-1. The first pixel region PXA-1, the second pixel region PXA-2, and the third pixel regions PXA-3 may have the same area.

Two adjacent pixel regions among the pixel regions PXA-1, PXA-2, and PXA-3 may have a predetermined shape (a predetermined area), and the two pixel regions may also be arranged repeatedly.

Referring to FIG. 4C, a display panel DP may include a base layer 110, a pixel circuit layer 120 disposed on the base layer 110, a display element layer 130 disposed on the pixel circuit layer 120, and a thin-film encapsulation layer 140 disposed on the display element layer 130.

Referring to FIG. 4C, the base layer 110 is illustrated as a single layer. The base layer 110 may include glass, but is not limited thereto and may include a synthetic resin such as polyimide.

The pixel circuit layer 120 may include a pixel driving circuit PC and at least one insulation layer. The pixel driving circuit PC may include a plurality of pixel driving elements. The pixel driving element may include a semiconductor pattern and a conductive pattern. The at least one insulation layer may be disposed on the semiconductor pattern and the conductive pattern. A driving element such as a transistor and a capacitor may be formed by a combination of the semiconductor pattern and the conductive pattern.

The pixel driving circuit PC may include a plurality of transistors S-TFT and O-TFT and a capacitor Cst. In FIG. 4C, a silicon transistor S-TFT and an oxide transistor O-TFT are illustrated as one example of the transistor. The pixel driving circuit PC in FIG. 4C is merely one example, and a configuration of the pixel driving circuit PC is not necessarily limited thereto. The pixel driving circuit PC may also include only one type of transistor among the silicon transistor S-TFT and the oxide transistor O-TFT.

A barrier layer 10br may be disposed on the base layer 110. The barrier layer 10br prevents foreign matters from being introduced from outside. The barrier layer 10br may include at least one inorganic layer. The barrier layer 10br may include a lower barrier layer 10br1 and an upper barrier layer 10br2. A first shielding electrode BMLa may be disposed between the lower barrier layer 10br1 and the upper barrier layer 10br2. The first shielding electrode BMLa may be disposed to correspond to the silicon transistor S-TFT. The first shielding electrode BMLa may include metal, for example, molybdenum. The first shielding electrode BMLa may receive a bias voltage.

A buffer layer 10bf may be disposed on the barrier layer 10br. The buffer layer 10bf may prevent a phenomenon in which metal atoms or impurities diffuse into a first semiconductor pattern SC1 thereabove from the base layer 110. The buffer layer 10bf may include at least one inorganic layer.

The first semiconductor pattern SC1 may be disposed on the buffer layer 10bf. The first semiconductor pattern SC1 may include a silicon semiconductor. For example, the silicon semiconductor may include amorphous silicon, polycrystalline silicon, etc. For example, the first semiconductor pattern SC1 may include low temperature polysilicon.

The first semiconductor pattern SC1 may have different electrical properties depending on whether the first semiconductor pattern is doped or not. A source region SE1, a channel region AC1 (or active region), and a drain region DE1 of the silicon transistor S-TFT may be formed in the first semiconductor pattern SC1. The source region SE1 and the drain region DE1 may extend in directions opposite to each other from the channel region AC1 in a cross-sectional view.

A first insulation layer 10 may be disposed on the buffer layer 10bf. The first insulation layer 10 may cover the first semiconductor pattern SC1. The first insulation layer 10 may be an inorganic layer. An inorganic layer of the pixel circuit layer 120 to be described later as well as the first insulation layer 10 may have a single- or multi-layered structure, and may include at least one of the aforementioned materials, but an embodiment of the inventive concept is not limited thereto.

A gate GT1 of the silicon transistor S-TFT is disposed on the first insulation layer 10. The gate GT1 may be a portion of a metal pattern (or conductive pattern). The gate GT1 overlaps the channel region AC1. The gate GT1 may be a mask in a process of doping the first semiconductor pattern SC1. A first electrode CE10 of the capacitor Cst is disposed on the first insulation layer 10. In a plan view, the first electrode CE10 may have an integrated shape with the gate GT1. When the first electrode CE10 is defined as a first conductive pattern, the gate GT1 may be defined as a second conductive pattern. However, the first conductive pattern does not mean only the first electrode CE10, nor does the second conductive pattern mean only the gate GT1. In this specification, the “first conductive pattern” means any one conductive pattern physically or functionally, and the “second conductive pattern” may mean another conductive pattern distinguished from the first conductive pattern.

A second insulation layer 20 may be disposed on the first insulation layer 10 and may cover the gate GT1. In an embodiment of the inventive concept, an additional upper electrode overlapping the gate GT1 may also be disposed on the second insulation layer 20. A second electrode CE20 overlapping the first electrode CE10 may be disposed on the second insulation layer 20. The upper electrode may have an integrated shape with the second electrode CE20 on a plane.

A second shielding electrode BMLb is disposed on the second insulation layer 20. The second shielding electrode BMLb may be disposed to corresponding to the oxide transistor O-TFT. In an embodiment of the inventive concept, the second shielding electrode BMLb may be omitted. A third insulation layer 30 may be disposed on the second insulation layer 20. A second semiconductor pattern SC2 may be disposed on the third insulation layer 30. A source region SE2, a channel region AC2 (or active region), and a drain region DE2 of the oxide transistor O-TFT may be formed in the second semiconductor pattern SC2. The second semiconductor pattern SC2 may include a metal oxide semiconductor. A fourth insulation layer 40 may be disposed on the third insulation layer 30. As illustrated in FIG. 4C, the fourth insulation layer 40 may cover the second semiconductor pattern SC2.

A gate GT2 of the oxide transistor O-TFT may be disposed on the fourth insulation layer 40. The gate GT2 of the oxide transistor O-TFT may be a portion of a metal pattern. The gate GT2 of the oxide transistor O-TFT may overlap the channel region AC2. A fifth insulation layer 50 may be disposed on the fourth insulation layer 40, and the fifth insulation layer 50 may cover the gate GT2. The first insulation layer 10 to the fifth insulation layer 50 may each be an inorganic layer.

The fifth insulation layer 50 has a relatively flat upper surface compared to the insulation layer (for example, the fourth insulation layer 40) disposed thereunder. This is because a polishing process is performed on the fifth insulation layer 50 during a manufacturing process of a display panel. On the contrary, for example, the fourth insulation layer 40 has an uneven upper surface due to a stepped portion made by the semiconductor pattern or the conductive pattern disposed under the fourth insulation layer 40. An inorganic layer formed through a deposition process has a uniform thickness by reflecting a stepped portion thereunder.

In an embodiment of the inventive concept, when the fifth insulation layer 50 includes an organic material, the fifth insulation layer 50 may have a relatively flat upper surface without a polishing process. An upper surface of an organic layer formed through inkjet and coating processes may have a planarized surface by covering a stepped portion thereunder.

A first connection electrode CNP1, a second connection electrode CNP2, and a third connection electrode CNP3 may be disposed on the fifth insulation layer 50. A defect rate of the first to third connection electrodes CNP1, CNP2, and CNP3 which are formed on a flat upper surface may be reduced. A detailed description thereof is referred to a manufacturing method.

The first connection electrode CNP1, the second connection electrode CNP2, and the third connection electrode CNP3 may be formed through the same process, thereby having the same material and the same stacked structure. The first connection electrode CNP1 may be electrically connected to the drain region DE1 of the first semiconductor pattern SC1 through a first contact hole PCH1 that penetrates the first to fifth insulation layers 10, 20, 30, 40, and 50. The second connection electrode CNP2 may be electrically connected to the source region SE2 of the oxide transistor O-TFT through a second contact hole PCH2 that penetrates the fourth and fifth insulation layers 40 and 50. The third connection electrode CNP3 may be electrically connected to the first electrode CE10 through a third contact hole PCH3 that penetrates the second to fifth insulations layers 20, 30, 40, and 50.

When the first electrode CE10 is defined as a first conductive pattern, the third connection electrode CNP3 may be defined as a second conductive pattern. In an embodiment of the inventive concept, the first electrode CE10 and another first conductive pattern may be disposed under the fifth insulation layer 50, the third connection electrode CNP3 and another second conductive pattern may be disposed on the fifth insulation layer 50, and thus may be connected to each other through a contact hole that penetrates the barrier layer 10br, the buffer layer 10bf, and a corresponding layer among the first to fifth insulation layers 10, 20, 30, 40, and 50.

In FIG. 4D, the first connection electrode CNP1 is illustrated in detail as one example of the second conductive pattern. Hereinafter, the second conductive pattern is described in detail with reference to FIG. 4D.

The first connection electrode CNP1 may be in direct contact with the drain region DE1 through the first contact hole PCH1. The contact hole PCH1 may have a depth DT and a width DM. The first connection electrode CNP1 may include a first conductive layer SDL and a second conductive layer EPL.

The first conductive layer SDL may be in contact with the upper surface of the fifth insulation layer 50, an inner surface of the first contact hole PCH1, and the drain region DE1 of the first semiconductor pattern SC1. The first conductive layer SDL may have a multi-layered structure. In this embodiment, the first conductive layer SDL with a two-layer structure is exemplarily illustrated. The first conductive layer SDL may include a titanium layer SDL1 and a copper layer SDL2 disposed on the titanium layer SDL1. A thickness of the titanium layer SDL1 may be about 100 Å to about 200 Å and a thickness of the copper layer SDL2 may be about 300 Å to about 3000 Å. A first side surface of the titanium layer SDL1 and a first side surface of the copper layer SDL2 which constitute a first side surface of the first conductive layer SDL may be aligned to each other. This is because the titanium layer SDL1 and the copper layer SDL2 are etched in the same process. A detailed description thereof is referred to a manufacturing method.

The second conductive layer EPL is disposed on the first conductive layer SDL. The second conductive layer EPL may have a greater thickness than the first conductive layer SDL. The second conductive layer EPL may contain copper and may cover and be in contact with a first side surface SS1 of the first conductive layer SDL. This is because the second conductive layer EPL is formed after the first conductive layer SDL is etched. A detailed description thereof is referred to a manufacturing method.

The second conductive layer EPL may completely fill the first contact hole PCH1 on the first conductive layer SDL. The second conductive layer EPL formed by an electrolytic plating method sufficiently fills the first contact hole PCH1 which has a great depth, and does not form a void within the first contact hole PCH1. Accordingly, contact resistance of the first connection electrode CNP1 with respect to the drain region DE1 may be reduced, and a defect of the first connection electrode CNP1 may be reduced.

FIG. 4E exemplarily illustrates a connection electrode formed by general DC sputtering. A conductive material is deposited on an inner surface of a contact hole, but a greater amount of the conductive material is deposited on an upper surface of an insulation layer, so that the contact hole is not filled and a defect in which a void is created within the contact hole is shown.

The defect of the void shown in FIG. 4E occurs more frequently as a depth of the contact hole is greater than a diameter of the contact hole. When the depth of the contact hole is about 1.6 times or more greater than the diameter of the contact hole, the defect in which a void is created within the contact hole occurs. However, in the first connection electrode CNP1 according to this embodiment, such a defect may be inhibited even when the depth of the contact hole is about 1.6 times or more greater than the diameter of the contact hole.

Referring to FIG. 4C again, a sixth insulation layer 60 may be disposed on the fifth insulation layer 50. The sixth insulation layer 60 may be an organic layer. A data line DL may be disposed on the sixth insulation layer 60. The data line DL may be electrically connected to the first connection electrode CNP1 through a fourth contact hole PCH4 that penetrates the sixth insulation layer 60. However, this is merely one example, and the data line DL may also be connected to another conductive pattern disposed under the sixth insulation layer 60.

The data line DL may have the same stacked structure as the first connection electrode CNP1 described with reference to FIG. 4D. However, an embodiment of the inventive concept is not limited thereto, and the data line DL may also include a single-layered metal layer.

A seventh insulation layer 70 may be disposed on the sixth insulation layer 60, and may cover the data line DL. A light-emitting element LD1 may be disposed on the seventh insulation layer 70. The light-emitting element LD1 may include a first electrode AE1, a light-emitting layer EL, and a second electrode CE. In this embodiment, the first electrode AE1 may be an anode, and the second electrode CE may be a cathode.

The first electrode AE1 may be a (semi)transmissive electrode or a reflective electrode. The first electrode AE1 may include a stacked structure of ITO/Ag/ITO sequentially stacked. Although not illustrated in FIG. 4C, the first electrode AE1 may be electrically connected to the transistor disposed in the pixel circuit layer 120.

A pixel defining layer PDL may be disposed on the seventh insulation layer 70. The pixel defining layer PDL may be an organic layer. The pixel defining layer PDL may have a property of absorbing light, and, for example, the pixel defining layer PDL may have a color of black. The pixel defining layer PDL may include a black coloring agent. The black coloring agent may include black dye and black pigment. The black coloring agent may contain metal such chrome, an oxide thereof, or carbon black. The pixel defining layer PDL may correspond to a light-blocking pattern which has a light-blocking property.

The pixel defining layer PDL may cover a portion of the first electrode AE1. For example, an opening PDL-OP exposing a portion of the first electrode AE1 may be defined in the pixel defining layer PDL. A light-emitting region LA-1 may be defined to correspond to the opening PDL-OP. FIG. 4C exemplarily illustrates one light-emitting region LA-1 corresponding to the first light-emitting region LA-1 in FIG. 4A. In other words, the first light-emitting region LA-1 may be defined to correspond to the portion of the first electrode AE1 exposed by the opening PDL-OP.

In an embodiment of the inventive concept, a hole control layer may be disposed between the first electrode AE1 and the light-emitting layer EL. The hole control layer may include a hole transport layer and may further include a hole injection layer. An electron control layer may be disposed between the light-emitting layer EL and the cathode CE. The electron control layer may include an electron transport layer and may further include an electron injection layer.

The thin-film encapsulation layer 140 may cover the light-emitting element LD1. The thin-film encapsulation layer 140 may include an inorganic encapsulation layer 141, an organic encapsulation layer 142, and an inorganic encapsulation layer 143 which are sequentially stacked, but the layers that constitute the thin-film encapsulation layer 140 are not necessarily limited thereto. The inorganic encapsulation layers 141 and 143 may include a silicon nitride layer, a silicon oxynitride layer, a silicon oxide layer, a titanium oxide layer, an aluminum oxide layer, or the like. Each of the inorganic encapsulation layers 141 and 143 may also have a multi-layered structure. The organic encapsulation layer 142 may include an acrylate-based organic layer, and is not limited thereto.

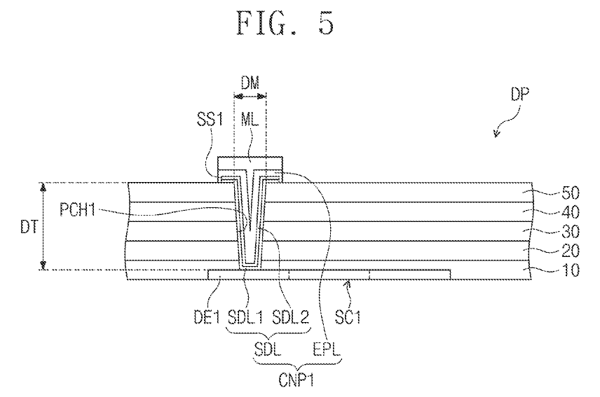

FIG. 5 is a cross-sectional view of a display panel DP according to an embodiment of the inventive concept. FIG. 5 illustrates a cross-sectional area corresponding to FIG. 4D. Hereinafter, a detailed description of components that are the same as the components described above is referred to the description made with reference to FIGS. 4C and 4D.

A first connection electrode CNP1 may further include a third conductive layer ML (or an additional conductive layer) disposed on a second conductive layer EPL. It is illustrated that a side surface of the third conductive layer ML is aligned with a side surface of the second conductive layer EPL, but an embodiment of the inventive concept is not limited thereto. The third conductive layer ML may also cover or be contact with the side surface of the second conductive layer EPL. The second conductive layer EPL may fill a portion of a first contact hole PCH1 on a first conductive layer SDL and the third conductive layer ML may fill a remaining portion of the first contact hole PCH1 on the second conductive layer EPL.

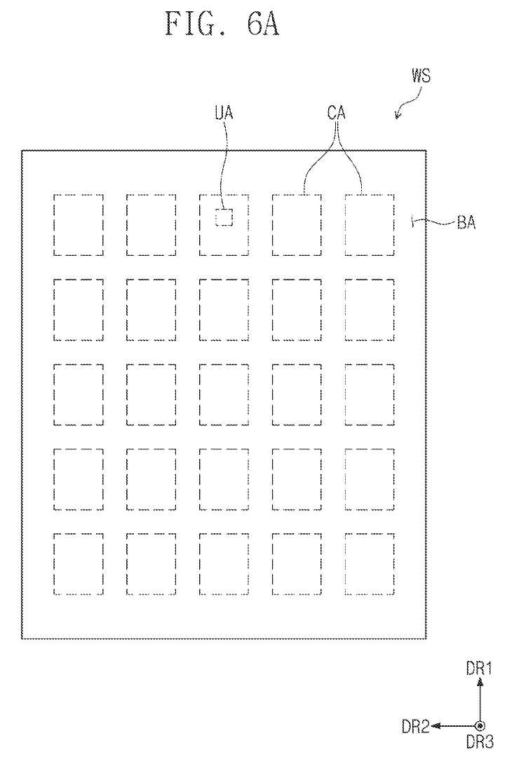

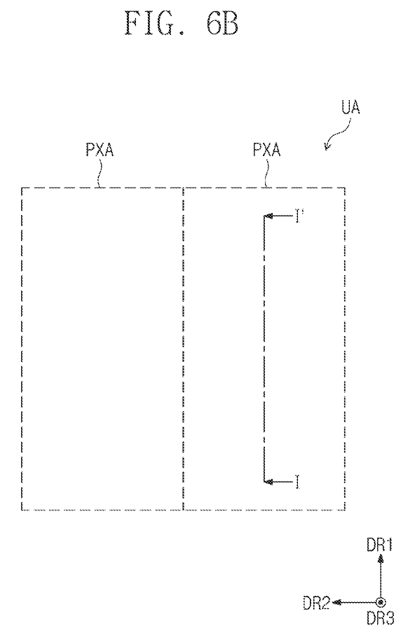

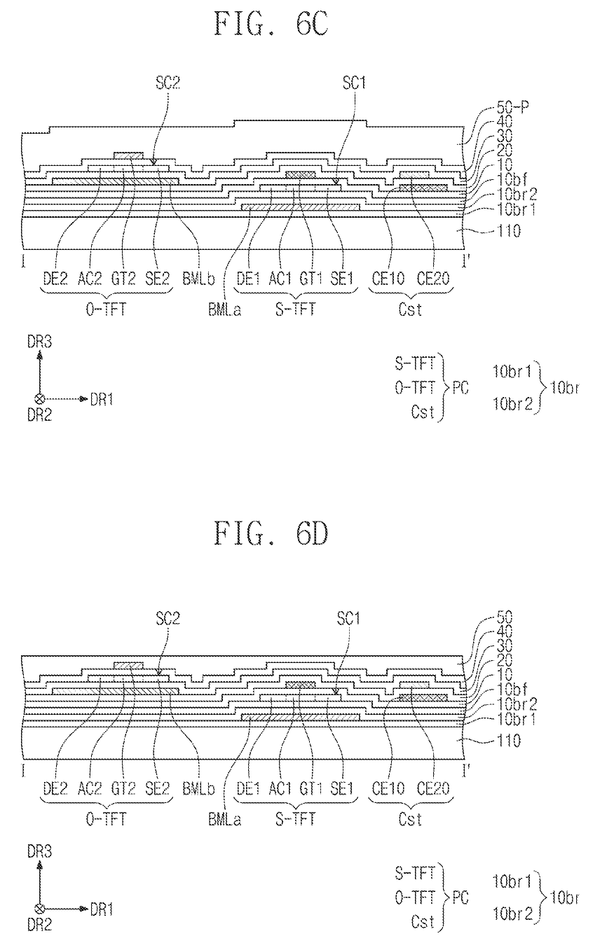

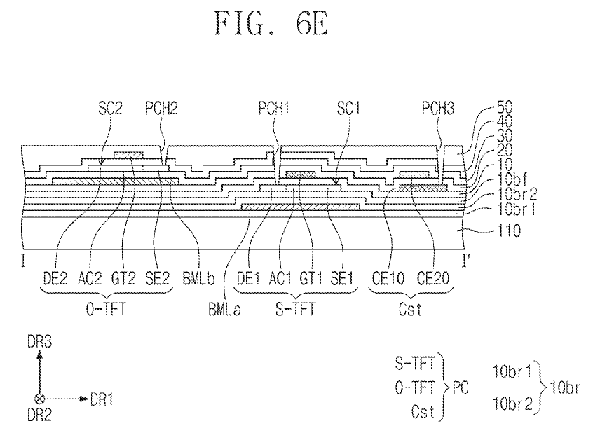

FIGS. 6A to 8F illustrate a method for manufacturing a display panel DP according to an embodiment of the inventive concept.

FIG. 6A illustrates one work substrate WS. The work substrate WS includes a plurality of cell regions CA and a boundary region BA between the cell regions CA. After a manufacturing process of the display panel DP is completed, each of the cell regions CA is separated from the work substrate WS. Each of the separated cell regions CA corresponds to the display panel DP in FIG. 3.

The same process is performed on the cell regions CA at each step of the manufacturing process of the display panel DP. Accordingly, at each step, the cell regions CA include substantially the same metal pattern, substantially the same semiconductor pattern, or substantially the same insulation layer.

FIG. 6B is an enlarged view of a unit region UA within the cell region CA. A plurality of unit regions UA are disposed within the cell region CA. The unit region UA includes two pixel regions PXA, which are adjacent to each other in the same pixel row PXR among the first pixel regions PXA-1, the second pixel regions PXA-2, and the third pixel regions PXA-3 illustrated in FIG. 4B.

The same process is performed on the plurality of unit regions UA at each step of the manufacturing process of the display panel DP. Accordingly, at each step, the plurality of unit regions UA include substantially the same metal pattern, substantially the same semiconductor pattern, or substantially the same insulation layer. The two pixel regions PXA may have substantially the same metal pattern, semiconductor pattern, or insulation layer. In addition, the two pixel regions PXA may have metal patterns, semiconductor patterns, or insulation layers which are substantially symmetrical to each other.

FIG. 6C illustrates a cross section corresponding to line I-I' of the pixel region PXA in FIG. 6B. FIG. 6C illustrates the cross section based on the same cross section in FIG. 4C. Unlike FIG. 4C, FIG. 6C illustrates a state during the manufacturing process of the display panel DP. According to FIG. 6C, a silicon transistor S-TFT, an oxide transistor O-TFT, and a capacitor Cst are formed on a base layer 110. A step of forming at least one conductive pattern and a step of forming at least one semiconductor pattern are performed to each of the two pixel regions PXA.

In addition, a plurality of insulation layers 10br, 10bf, 10, 20, 30, and 40 are formed during the formation of the silicon transistor S-TFT, oxide transistor O-TFT, and capacitor Cst. The plurality of insulation layers 10br, 10bf, 10, 20, 30, and 40 may be formed through a deposition process of an inorganic material.

In addition, a preliminary fifth insulation layer 50-P is formed on the fourth insulation layer 40. The preliminary fifth insulation layer 50-P may be formed through a deposition process of an inorganic material. The preliminary fifth insulation layer 50-P has an uneven upper surface. The silicon transistor S-TFT, oxide transistor O-TFT, and capacitor Cst are arranged in a predetermined rule under the preliminary fifth insulation layer 50-P. The silicon transistor S-TFT, the oxide transistor O-TFT, and the capacitor Cst create a stepped portion on the insulation layer disposed thereabove.

Referring to FIG. 6D, an upper surface of the preliminary fifth insulation layer 50-P in FIG. 6C is planarized. A stepped portion of the preliminary fifth insulation layer 50-P may be planarized through a chemical mechanical polishing (CMP) process. The planarized upper surface may improve uniformity (uniformity of thickness or line width) of a conductive pattern that is formed in an electrolytic plating process to be described later. Hereinafter, the planarized preliminary fifth insulation layer 50-P is defined as a fifth insulation layer 50.

Referring to FIG. 6E, a first contact hole PCH1, a second contact hole PCH2, and a third contact hole PCH3 may be formed in the first to fifth insulation layer 10 to 50. Each of the first contact hole PCH1, the second contact hole PCH2, and the third contact hole PCH3 penetrates corresponding insulating layers among the first to fifth insulating layers 10 to 50. The first to fifth insulation layer 10 to 50 is patterned using a photo-lithographic process.

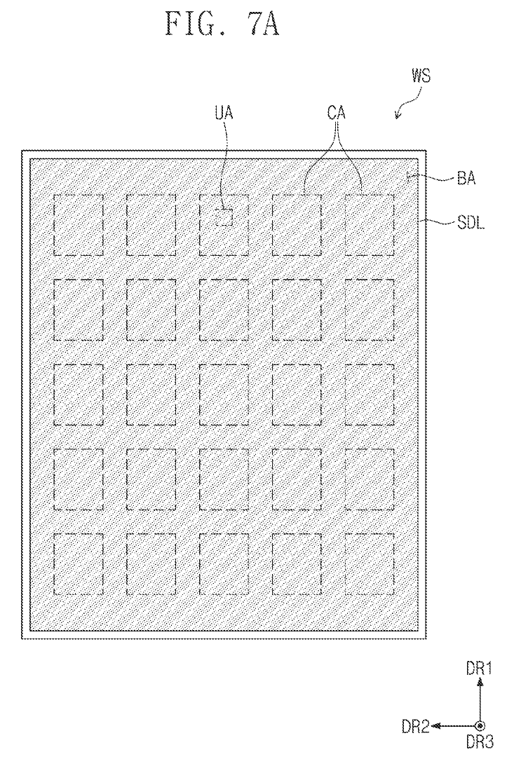

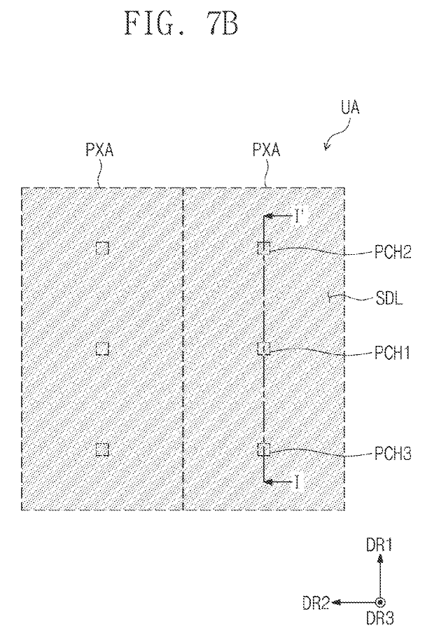

FIGS. 7A and 7B illustrate a step after the manufacturing step of the display panel DP illustrated in FIG. 6E. A seed conductive layer SDL is formed entirely on a work substrate WS. FIG. 7A illustrates that an edge of the work substrate WS is exposed from the seed conductive layer SDL so as to distinguish between the work substrate WS and the seed conductive layer SDL, but an embodiment of the inventive concept is not limited thereto. Substantially, the edge of the work substrate WS and an edge of the seed conductive layer SDL may be aligned to each other.

The seed conductive layer SDL may be formed through a metal deposition process. A sputtering process may be used for the formation of the seed conductive layer SDL. After forming a first conductive layer, a second conductive layer of a different material may be formed consecutively.

The seed conductive layer SDL may be connected to a corresponding pattern among the conductive pattern CE10 (see FIG. 6E) and the semiconductor patterns SC1 and SC2 (see FIG. 6E) through each of the first contact hole PCH1, the second contact hole PCH2, and the third contact hole PCH3.

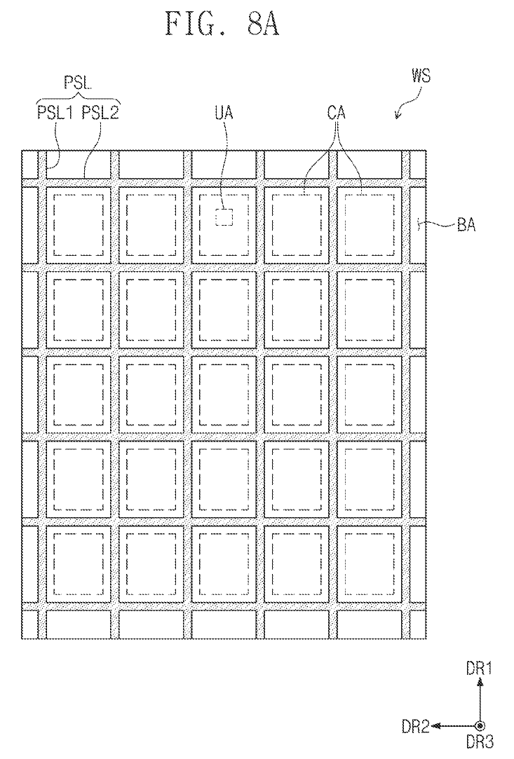

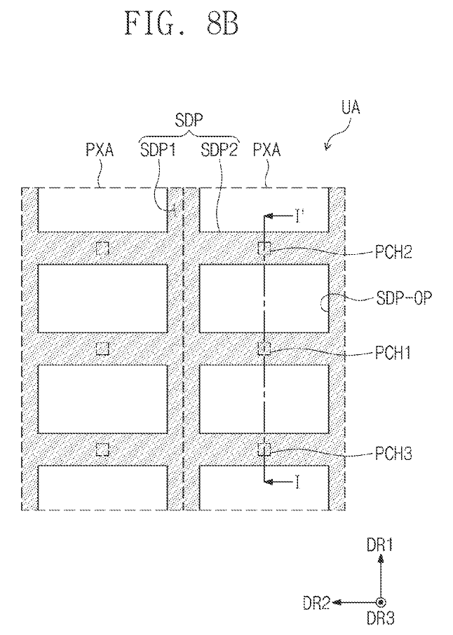

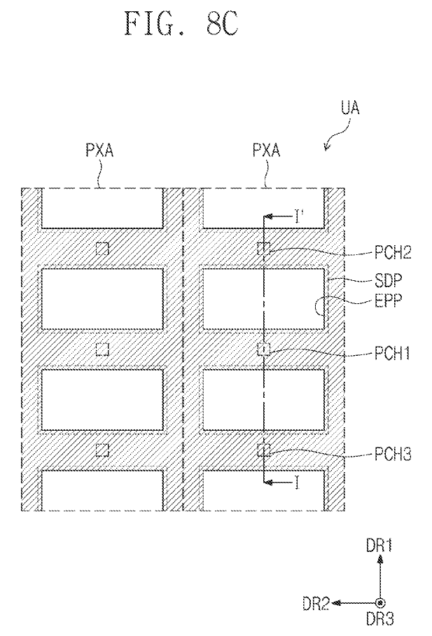

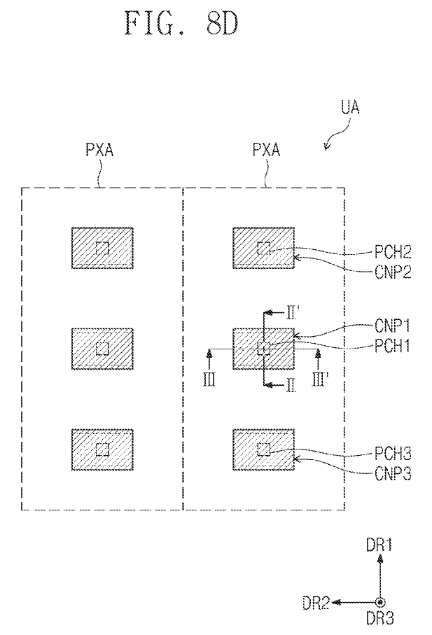

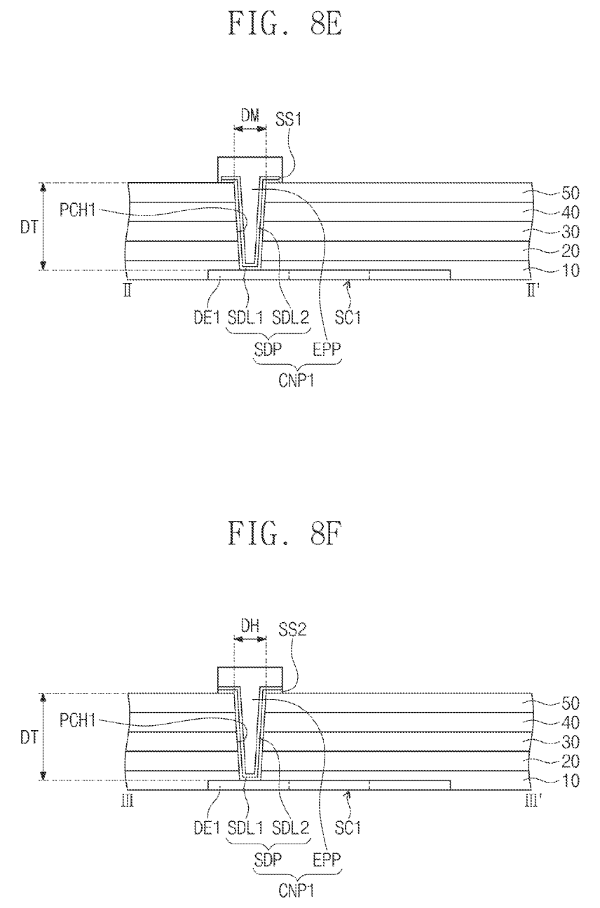

As illustrated in FIGS. 8A and 8B, the seed conductive layer SDL of FIGS. 7A and 7B is patterned. After forming a photoresist layer on the seed conductive layer SDL, the seed conductive layer SDL is patterned through the photo-lithographic process that includes exposure, development, and etching processes. Then, a remaining photoresist pattern is removed.

Referring to FIG. 8A, a voltage supply line PSL may be formed from the seed conductive layer SDL of FIGS. 7A and 7B in the boundary region BA around the cell regions CA. The voltage supply line PSL may include a plurality of first components PSL1 extending in a first direction DR1 and a plurality of second components PSL2 extending in a second direction DR2. The first components PSL1 and the second components PSL2 may have an integrated shape. The voltage supply line PSL may be described as having a mesh shape, and may also be described as having a grid shape.

Referring to FIG. 8B, a seed conductive pattern SDP overlapping the pixel region PXA may be formed of the seed conductive layer SDL of FIGS. 7A and 7B. The seed conductive pattern SDP may overlap the first contact hole PCH1, the second contact hole PCH2, and the third contact hole PCH3. The seed conductive pattern SDP corresponds to the first conductive layer SDL in FIG. 4D.

The seed conductive pattern SDP may also include at least one first component PSL1 extending in the first direction DR1 and at least one second component PSL2 extending in the second direction DR2. The plurality of first components PSL1 and the plurality of second components PSL2 may be disposed in one cell region CA, and the plurality of first components PSL1 and the plurality of second components PSL2 may have an integrated shape. Such a shape may also be described by a plurality of openings SDP-OP being formed in the seed conductive pattern SDP.

As illustrated in FIG. 8B, a plating pattern EPP which is in contact with an upper surface and a side surface of the seed conductive pattern SDP is formed through an electrolytic plating method. The plating pattern EPP corresponds to the second conductive layer EPL in FIG. 4C.

The plating pattern EPP is formed only in a region where the seed conductive pattern SDP is disposed. However, the plating pattern EPP may be formed not only on an upper surface of the seed conductive pattern SDP but also on a portion or all of a side surface of the seed conductive pattern SDP. In the electrolytic plating process, a metal layer may also grow in the seed conductive pattern SDP since a reduction reaction occurs with a metal ion by providing an electron to the side surface of the seed conductive pattern SDP, as well.

A thickness of the plating pattern EPP may be determined depending on progress time of the electrolytic plating process and power supply amount. The thickness of the plating pattern EPP is proportional to each of the progress time of the electrolytic plating process and the power supply amount. Even under a low power condition, as the process time increases, the thickness of the plating pattern EPP may be increased. Under a high power condition, the thickness of the plating pattern EPP may be increased even when the process time is short.

The seed conductive pattern SDP described with reference to FIGS. 8B and 8A may have an integrated shape with the voltage supply line PSL of FIGS. 8A. This is because the seed conductive pattern SDP and the voltage supply line PSL are all connected to a reduction electrode in the electrolytic plating process. Accordingly, a plating pattern may further be formed on an upper surface and side surface of the voltage supply line PSL like the plating pattern EPP formed on the top and side surfaces of the seed conductive pattern SDP.

Referring to FIGS. 8C and 8D, the plating pattern EPP and the seed conductive pattern SDP are patterned. Accordingly, at least one of conductive patterns CNP1, CNP2, and CNP3 is formed from a stacked structure of the seed conductive pattern SDP and the plating pattern EPP. FIG. 8D exemplarily illustrates first to third conductive patterns CNP1, CNP2, and CNP3, and the first to third conductive patterns CNP1, CNP2, and CNP3 may correspond to the first to third connection electrodes CNP1, CNP2, and CNP3 in FIG. 4C. An area of the plating pattern EPP and the seed conductive pattern SDP is reduced as shown in FIG. 8C to FIG. 8D since a portion of the stacked structure is removed during the patterning of the stacked structure of the plating pattern EPP and the seed conductive pattern SDP.

FIG. 8E illustrates a cross section along one direction (a first direction DR1 in this embodiment) of one conductive pattern CNP1 illustrated in FIG. 8D. FIG. 8F illustrates a cross section along another direction (a second direction DR2 in this embodiment) of one conductive pattern CNP1 illustrated in FIG. 8D.

FIG. 8E may be substantially the same as FIG. 4D. However, the first conductive layer SDL of FIG. 4D is depicted as the seed conductive pattern SDP, and the second conductive layer EPL is depicted as the plating pattern EPP. The contact hole PCH1 may have a depth DT and a width DM. As described with reference to FIG. 8C, since the plating pattern EPP is formed after the seed conductive pattern SDP is formed, a first side surface SS1 of the seed conductive pattern SDP may be covered by the plating pattern EPP. In other words, one side surface of the plating pattern EPP is not continuous with the first side surface SS1 of the seed conductive pattern SDP, and is not aligned. Even when the first side surface SS1 of the seed conductive pattern SDP is not covered by the plating pattern EPP, the plating pattern EPP may be in contact with the first side surface SS1 of the seed conductive pattern SDP.

Referring to FIG. 8F, a second side surface SS2 of the seed conductive pattern SDP may be aligned with another side surface of the plating pattern EPP. Referring to FIGS. 8C and 8D, this is because the plating pattern EPP and the seed conductive pattern SDP are patterned simultaneously.

So as to form the first connection electrode CNP1 illustrated in FIG. 5, a third conductive layer ML may further be formed after the patterning in FIG. 8D. After a metal layer covering the patterned plating pattern EPP is formed through a deposition process, the metal layer may be patterned through a photolithography process.

The electrolytic plating time may be shortened by decreasing growth time of the second conductive layer EPL illustrated in FIG. 8D. Nevertheless, a remaining region of the contact hole with a small depth may be filled with the metal layer through a sputtering method.

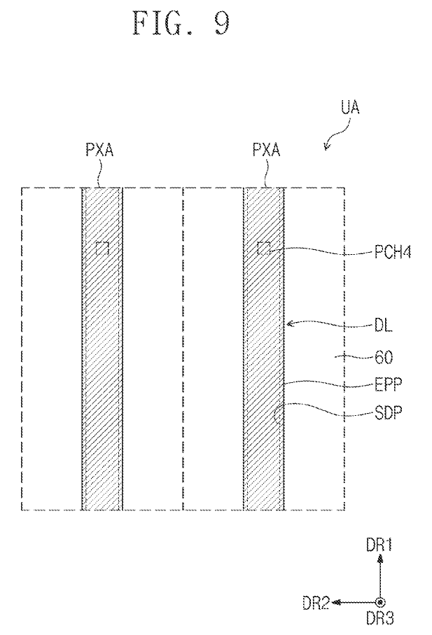

FIG. 9 is a plan view illustrating one step of a method for manufacturing a display panel DP according to an embodiment of the inventive concept.

Referring to FIG. 9, a data line DL may be formed on a sixth insulation layer 60 where a fourth contact hole PCH4 is formed. The data line DL may include the seed conductive pattern SDP and the plating pattern EPP which are described with reference to FIGS. 8B and 8C. However, the seed conductive pattern SDP of the data line DL may include only a component extending in a first direction DR1. Accordingly, the plating pattern EPP may also include only a component extending in the first direction DR1. Additionally, in the data line DL, the patterning process of the stacked structure of the seed conductive pattern SDP and the plating pattern EPP described with refence to FIG. 8D may not be performed.

So as to manufacture the display panel DP illustrated in FIG. 4C, an additional process may further be performed. A seventh insulation layer 70 may be formed on the sixth insulation layer 60, and a light-emitting element LD1 and a pixel defining layer PDL may be formed on the seventh insulation layer 70. Such a process may be performed by a known method, and is not limited to a particular method.

A conductive pattern formed by an electrolytic plating method sufficiently fills a deep contact hole, and does not form a void within the contact hole. Accordingly, contact resistance of the conductive pattern is reduced, and a defect of the conductive pattern is reduced.

A seed conductive pattern may be formed from a seed conductive layer, and then a plating pattern may be formed in a relatively small area, thereby reducing amount of power used in the electrolytic plating method. In addition, the electrolytic plating time may be reduced.

In the above, description has been made with reference to embodiments of the inventive concept, but those skilled or of ordinary skill in the art may understand that various modifications and changes may be made to the inventive concept insofar as such modifications and changes do not depart from the spirit and technical scope of the inventive concept set forth in the claims to be described later. Therefore, the technical scope of the inventive concept is not to be limited to the contents stated in the detailed description of the specification, but should be determined by the claims.

What is claimed is:

1. A display device comprising:
a base layer;
a first conductive pattern disposed on the base layer;
a semiconductor pattern disposed on the base layer;
at least one insulation layer disposed on the first conductive pattern and the semiconductor pattern;
a second conductive pattern disposed on the at least one insulation layer, and electrically connected to the first conductive pattern or the semiconductor pattern through a contact hole which penetrates the at least one insulation layer; and
a light-emitting element disposed on the second conductive pattern,
wherein the second conductive pattern includes a first conductive layer which is in contact with an upper surface of the at least one insulation layer, an inner surface of the contact hole, and a corresponding pattern of the first conductive pattern or the semiconductor pattern and a second conductive layer which is disposed on the first conductive layer and in contact with a first side surface of the first conductive layer on the upper surface of the at least one insulation layer.

2. The display device of claim 1, wherein the first conductive layer comprises a titanium layer and a copper layer disposed on the titanium layer, and a side surface of the titanium layer and a side surface of the copper layer are aligned.

3. The display device of claim 2, wherein a thickness of the titanium layer is about 100 Å to about 200 Å and a thickness of the copper layer is about 300 Å to about 3000 Å.

4. The display device of claim 1, wherein a thickness of the second conductive layer is greater than a thickness of the first conductive layer.

5. The display device of claim 4, wherein the second conductive layer completely fills the contact hole on the first conductive layer.

6. The display device of claim 1, wherein a depth of the contact hole is about 1.6 times or more greater than a diameter of the contact hole.

7. The display device of claim 1, wherein one side surface of the second conductive layer is aligned with a second side surface of the first conductive layer which is different from the first side surface of the first conductive layer on the upper surface of the at least one insulation layer.

8. The display device of claim 1, further comprising a third conductive layer disposed on the second conductive layer,
wherein the second conductive layer fills a portion of the contact hole on the first conductive layer, and the third conductive layer fills a remaining portion of the contact hole on the second conductive layer.

9. The display device of claim 1, wherein the at least one insulation layer comprises a first inorganic layer, and a second inorganic layer which is disposed on the first inorganic layer and has an upper surface in contact with the second conductive pattern and an upper surface of the second inorganic layer is flatter than an upper surface of the first inorganic layer.

10. The display device of claim 1, wherein the at least one insulation layer comprises an organic layer which has an upper surface in contact with the second conductive pattern.

11. An electronic apparatus comprising:
a display device; and
a housing configured to accommodate the display device,
wherein the display device includes a base layer, a first conductive pattern disposed on the base layer, a semiconductor pattern disposed on the base layer, at least one insulation layer disposed on the first conductive pattern and the semiconductor pattern, a second conductive pattern disposed on the at least one insulation layer and electrically connected to the first conductive pattern or the semiconductor pattern through a contact hole which penetrates the at least one insulation layer, and a light-emitting element disposed on the second conductive pattern, and
wherein the second conductive pattern includes a first conductive layer which is in contact with an upper surface of the at least one insulation layer, an inner surface of the contact hole, and a corresponding pattern of the first conductive pattern or the semiconductor pattern, and a second conductive layer which is disposed on the first conductive layer and in contact with a first side surface of the first conductive layer on the upper surface of the at least one insulation layer.

12. The electronic apparatus of claim 11, wherein the electronic apparatus is a virtual reality device.

13. A method for manufacturing a display device, the method comprising:
forming a first conductive pattern and a semiconductor pattern in each of first and second cell regions of a work substrate;
forming, on the work substrate, at least one insulation layer which has a contact hole exposing a corresponding pattern among the first conductive pattern and the semiconductor pattern;
forming, on the insulation layer, a seed conductive layer overlapping each of the first and second cell regions, and connected to the corresponding pattern through the contact hole;
forming a seed conductive pattern by patterning the seed conductive layer;
forming, through an electrolytic plating method, a plating pattern which is in contact with an upper surface and a side surface of the seed conductive pattern; and
forming at least one conductive pattern by patterning the seed conductive pattern and the plating pattern.

14. The method of claim 13, wherein in the forming of the seed conductive pattern, a voltage supply line which has an integrated shape with the seed conductive pattern is further formed in a peripheral region of the first cell region and a peripheral region of the second cell region.

15. The method of claim 14, wherein the voltage supply line has a mesh shape in a plan view.

16. The method of claim 13, wherein a plurality of openings are defined in the seed conductive pattern.

17. The method of claim 13, wherein a thickness of the plating pattern is greater than a thickness of the seed conductive pattern, and
wherein the plating pattern completely fills the contact hole on the seed conductive pattern.

18. The method of claim 13, further comprising forming an additional conductive pattern on the at least one conductive pattern,
wherein the plating pattern fills a portion of the contact hole on the seed conductive pattern and the additional conductive pattern fills a remaining portion of the contact hole on the plating pattern.

19. The method of claim 13, further comprising planarizing an upper surface of the at least one insulation layer after the forming of the at least one insulation layer and before the forming of the seed conductive layer.

20. The method of claim 13, wherein the seed conductive pattern comprises a titanium layer and a copper layer disposed on the titanium layer, and
wherein a thickness of the titanium layer is about 100 Å to about 200 Å, and a thickness of the copper layer is about 300 Å to about 3000 Å.
